(19) United States
(12) Patent Application Publication
(10) Pub. No.: US 2022/0246754 A1
(43) Pub. Date: Aug. 4, 2022

(54) SEMICONDUCTOR DEVICE AND METHOD FOR MANUFACTURING A SEMICONDUCTOR DEVICE

(71) Applicant: Robert Bosch GmbH, Stuttgart (DE)

(72) Inventors: Alberto Martinez-Limia, Tuebingen (DE); Jan-Hendrik Alsmeier, Pfullingen (DE); Klaus Heyers, Reutlingen (DE); Stephan Schwaiger, Bodelshausen (DE); Wolfgang Feiler, Reutlingen (DE)

(21) Appl. No.: 17/621,893

(22) PCT Filed: Aug. 19, 2020
(86) PCT No.: PCT/EP2020/073213

§ 371 Date: Dec. 22, 2021

(30) Foreign Application Priority Data
Aug. 23, 2019 (DE) 10 2019 212 649.9

(51) Int. Cl. H01L 29/78; H01L 29/66

(52) U.S. Cl. CPC H01L 29/7813; H01L 29/66734; H01L 29/66068

(57) ABSTRACT

A semiconductor device. The semiconductor device includes a drift region of a first conductivity type, a channel region of a second conductivity type on the drift region, a source region of the first conductivity type on the channel region, a trench, which forms an insulated gate and extends through the source region and the channel region so that its bottom is situated in the drift region, and at least one buried region of the second conductivity type, which extends within the drift region from an edge region of the drift region to the trench and is in direct contact with a first subarea of a surface of the trench, a second subarea of a surface of the trench being in direct contact with the drift region, and the buried region being connected to the source region in an electrically conducting manner.

### FIELD

The present invention relates to a semiconductor device and to a method for manufacturing a semiconductor device.

### BACKGROUND INFORMATION

In a field effect transistor, e.g., a MOSFET, e.g., a silicon carbide MOSFET (SiC MOSFET), which has a gate that is formed to as a trench structure, preferably deep p+ structures are conventionally used for shielding the trench structure, which run laterally adjoining the trench and, if necessary, are also formed in an L shape including a buried leg beneath the trench. See, e.g., U.S. Pat. No. 8,946,726 B2 in this regard. Alternative approaches utilize an implantation of a p-region beneath the trench (as a so-called “bubble”), e.g., by implantation through the trench (see, e.g., U.S. Patent Application Publication No. US 2018/0097079 A1).

A conventional field shielding represents a compromise between a loading (as low as possible) of a gate oxide and an electrical resistance (as low as possible) during a current flow through a drift region of the MOSFET, e.g., through a JFET zone which may be formed within the drift region.

It is an object of the present invention to provide a semiconductor device and a method for the manufacture thereof, which offers protection as high as possible for the gate oxide, however, in the process, leaves a current flow through the semiconductor device as unimpaired as possible.

According to one aspect of the present invention, the object may be achieved by a semiconductor device which includes a drift region of a first conductivity type, a channel region of a second conductivity type on the drift region, a source region of the first conductivity type on the or in the channel region, a trench, which forms an insulated gate and extends through the source region and the channel region so that its bottom is situated in the drift region, and at least one buried region of the second conductivity type, which extends within the drift region from an edge region of the drift region to the trench and is in direct contact with a first subarea of a surface of the trench. In the process, the second conductivity type may be the opposite of the first conductivity type, a second subarea of a surface of the trench may be in direct contact with the drift region, and the buried region may be connected to the source region in an electrically conducting manner.

As is illustrated, the semiconductor device may be configured as a field effect transistor, e.g., MOSFET, in which a gate shielding is provided as a buried region which extends to the gate oxide so that the gate oxide is protected particularly well there. However, the buried region is designed in such a way that it only makes contact with the trench in a portion of the length of the trench, so that areas remain in which the (vertical) current flow through the (horizontally situated) buried region is not impaired or only insignificantly impaired.

According to one further aspect of the present invention, the object is achieved by a method for manufacturing a semiconductor device which includes forming a drift region of a first conductivity type, forming a channel region of a second conductivity type on the drift region, forming a source region of the first conductivity type on the or in the channel region, forming a trench, which forms an insulated gate and extends through the source region and the channel region so that its bottom is situated in the drift region, forming at least one buried region of the second conductivity type, which extends within the drift region from an edge region of the drift region to the trench and is in direct contact with a first subarea of a surface of the trench, and connecting the buried region to the source region in an electrically conducting manner. In the process, a second subarea of a surface of the trench may be in direct contact with the drift region, and the second conductivity type may be the opposite of the first conductivity type.

As is illustrated, a field effect transistor, e.g., a MOSFET, including the above-described properties is formed with the aid of the method.

In various exemplary embodiments of the present invention, the semiconductor device, for example the drift region and, if necessary, further regions, e.g., the source region, the channel region and/or the buried region, may be made up of silicon carbide (SiC). Accordingly, a SiC trench MOSFET having an effective shielding of its gate oxide may be provided in various exemplary embodiments.

In various exemplary embodiments of the present invention, a MOSFET including a shielding of its trench oxide is provided, while simultaneously limiting a saturation current through an effective JFET action.

In various exemplary embodiments of the present invention, the buried region may extend to beneath the trench. In this way, it is possible to achieve a partial enclosure of the trench bottom, and, in particular, of the trench edges in the region of their rounding, by the buried region, which results in a particularly effective field shielding of the trench bottom or the trench edges.

In various exemplary embodiments of the present invention, the buried region may extend, on a first side of the trench, from the edge region of the drift region to the trench and, on an opposing side of the trench, from the edge region of the drift region to the trench, and may in each case be in direct contact with a first subarea of a surface of the trench. This arrangement may be used, for example as an interdigital structure, in such a way that a higher density of the shielding regions is provided beneath the trench, while a distance between the buried regions in a third dimension is wide enough for good current conduction in the forward state. In this way, an effective field shielding of the trench bottom may be achieved by an “interdigital” structure of the buried regions, with good current flow in the forward state.

In various exemplary embodiments of the present invention, the buried region extending on two opposing sides of the trench from the edge region to the trench may furthermore mean that an adjustment invariance in the direction of the trench axis and a large overlap between the trench and the buried region in a direction perpendicular to the trench are present, which means that the configuration of the semiconductor device may be very maladjustment-tolerant.

Refinements of the aspects of the present invention are described herein. Specific embodiments of the present invention are shown in the figures and are explained in greater detail below.

### BRIEF DESCRIPTION OF THE DRAWINGS

FIG. 1 schematically shows a semiconductor device according to one specific embodiment of the present invention.

FIG. 2 schematically shows a semiconductor device according to one specific embodiment of the present invention.

FIG. 3 schematically shows a top view onto a cross-section of the semiconductor device from FIG. 1 or FIG. 2 in the direction of the arrow shown there.

FIGS. 4A through 4I show a schematic illustration of a method for manufacturing a semiconductor device according to one specific embodiment of the present invention.

FIGS. 5A through 5I show a schematic illustration of a method for manufacturing a semiconductor device according to one specific embodiment of the present invention.

FIG. 6 shows a flowchart of a method for manufacturing a semiconductor device according to one exemplary embodiment of the present invention.

### DETAILED DESCRIPTION OF EXAMPLE EMBODIMENTS

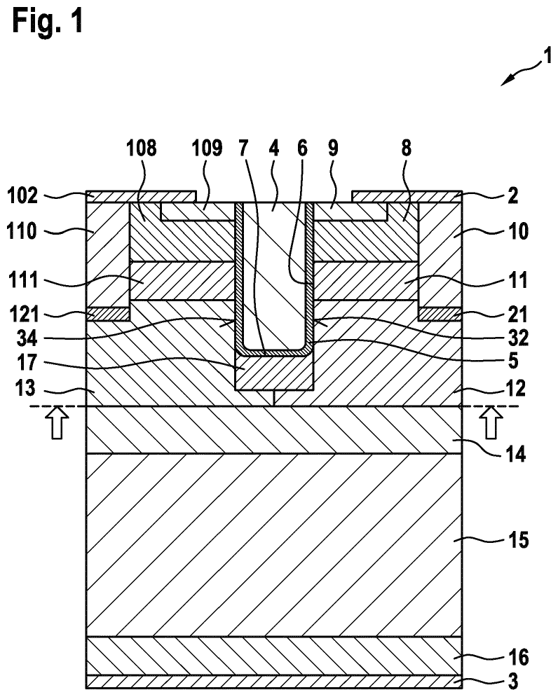

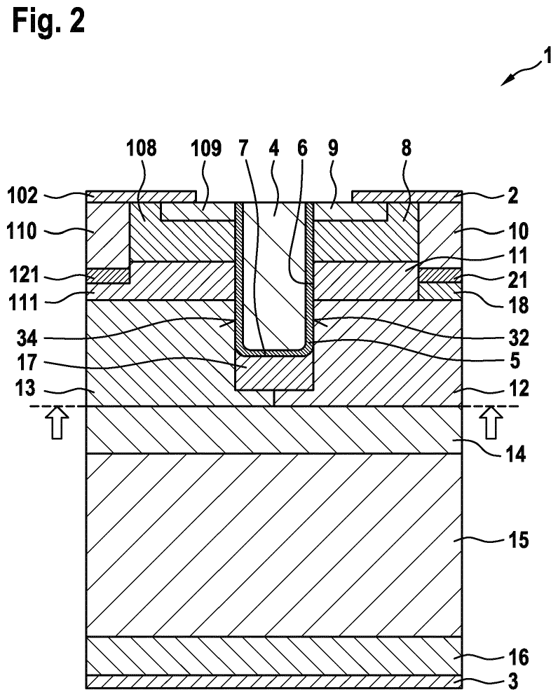

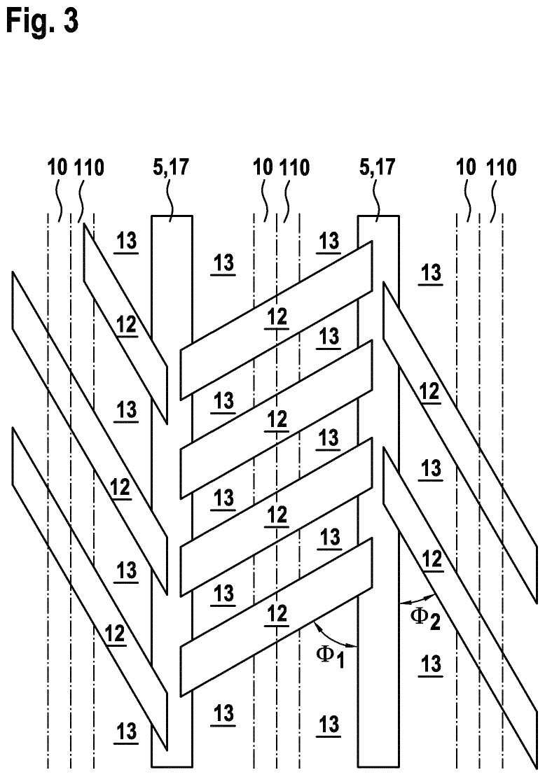

FIG. 1 and FIG. 2 each show a schematic cross-sectional view of a semiconductor device 1 according to one specific embodiment, and FIG. 3 shows a schematic top view onto a cross-section of the semiconductor device from FIG. 1 or FIG. 2 in the direction of the arrow shown there. FIG. 2 may be a preferred specific embodiment of semiconductor device 1.

In semiconductor device 1, some areas have a first conductivity type, and other areas have a second conductivity type which is the opposite of the first conductivity type. In the specific embodiments described hereafter, areas of the first conductivity type are n-doped, and areas of the second conductivity type are p-doped. In further specific embodiments, which are not shown, the conductivity types may be exactly reversed.

Semiconductor device 1 may, as is shown in FIG. 1 and FIG. 2, include a substrate 16, e.g., an SiC substrate or another wide band gap semiconductor substrate, which may be n-doped. Semiconductor device 1 is also referred to as a cell herein. The cell may be divided into two half cells by a trench 5, which is described below. An n-doped drift region (in the narrower sense) 15 may be formed above substrate 16, e.g., thereon. An n-doped region 14 may be situated thereabove, e.g., thereon, which is also referred to as an nSpreadingFET region 14 hereafter. At least one n-doped region 13, which is also referred to as an nJFET region 13 hereafter, and at least one p-doped buried region 12 may be situated next to one another, e.g., in a shared plane, thereabove, e.g., thereon. An n-doped region 11, 111 may be situated thereabove, e.g., thereon, which is also referred to as an nSpreading region 11, 111 hereafter. nSpreading region 11, 111 may, for example, be formed as a layer, the nSpreading region in the left half cell being denoted by 111 and in the right half cell being denoted by 11. A p-doped channel region 8, 108 (also referred to as body region) may, in turn, be situated thereabove, e.g., thereon, as two half cells. An n-doped source region 9, 109 may be formed as two half cells on or in channel region 8, 108. Drift region 15, nSpreadingFET region 14, nJFET region 13, and nSpreading region 11, 111 may jointly be understood as a drift region in the broader sense.

Semiconductor device 1 may furthermore include trench 5, which extends from an upper side of semiconductor device 1, e.g., from a surface of source region 9, 109, through source region 9, 109 and channel region 8, 108 into drift region (in the broader sense). A bottom of trench 5 may, for example, be situated in an area in which nJFET region 13 and p-doped buried region 12 abut one another, so that a surface of trench 5 is in contact with both nJFET region 13 and buried region 12. In various exemplary embodiments, e.g., as shown in FIGS. 1, 2, 3, 4I and 5I, the at least one buried region 12 may be situated with a portion beneath trench 5. The area of the surface of trench 5 which is in contact with buried region 12 is referred to as first subarea 32 here. The area of the surface of trench 5 which is in contact with nJFET region 13 is referred to as second subarea 34 here. Trench 5 may include a gate oxide 6, 7 at its walls, it being possible for gate oxide 7 to denote the gate oxide at the bottom of trench 5, which may be thicker than gate oxide 6 at the side walls of trench 5. Trench 5 may furthermore include a gate electrode 4, which may, for example, be formed of polysilicon. FIG. 1 and FIG. 2 furthermore show an optional, additional p-doped shielding region 17, which directly abuts the trench bottom and, e.g., is formed beneath trench 5. Even though gate electrode 4 and gate oxide 6, 7 may be considered as belonging to trench 5, the trench is denoted herein, in summary, by reference numeral 5.

In semiconductor device 1, buried region 12 may be connected to source region 9, 109 in an electrically conducting manner. For this purpose, p⁺-doped regions 10, 110, which extend in parallel to trench 5, may be situated in an edge region of each of the half cells of semiconductor device 1: mutually abutting regions having the same doping are connected to one another in an electrically conducting manner and thus form the electrically conducting connection. p⁺-doped regions 10, 110 and/or their tails 21, 121 may, as is shown in FIG. 1, extend into buried region 12, their doping being superimposed there on that of the buried region. In the left half cell in FIG. 1, it appears as if p⁺-doped region 110 would only extend into n-doped nJFET region 13. The schematic view from FIG. 3, however, shows that both in the left half cell and in the right half cell, in a direction perpendicular to the paper plane, a multitude of nJFET regions 13 and a multitude of buried regions 12 may alternate with one another. This means that p⁺-doped region 110, beneath or above the paper plane, may be in electrically conducting contact with (at least) one further of buried regions 12. In semiconductor device 1, trench 5 is always deeper than p⁺-doped regions 10, 110 and their tails 12, 121.

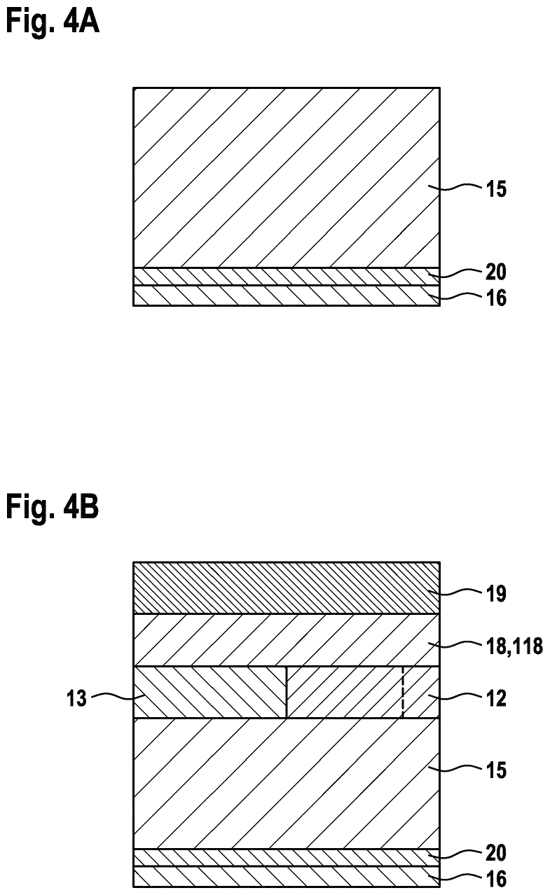

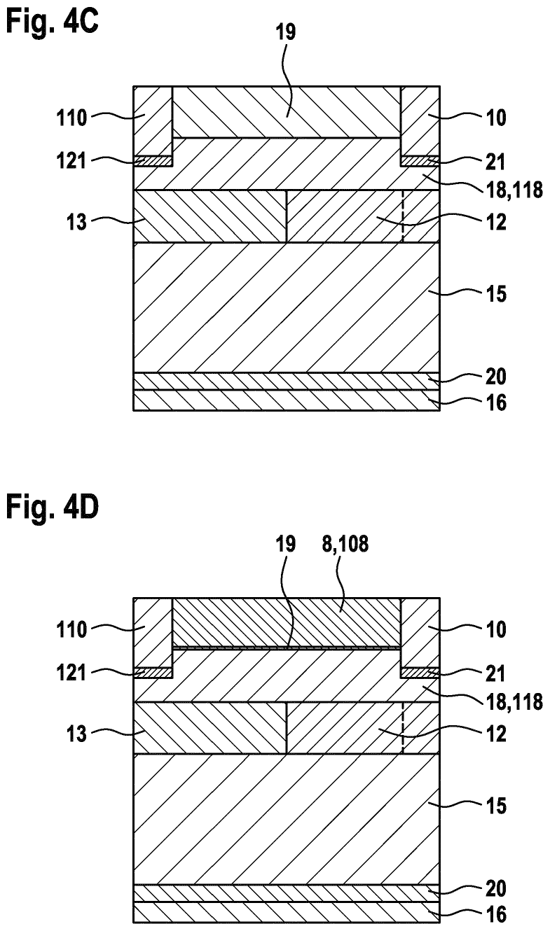

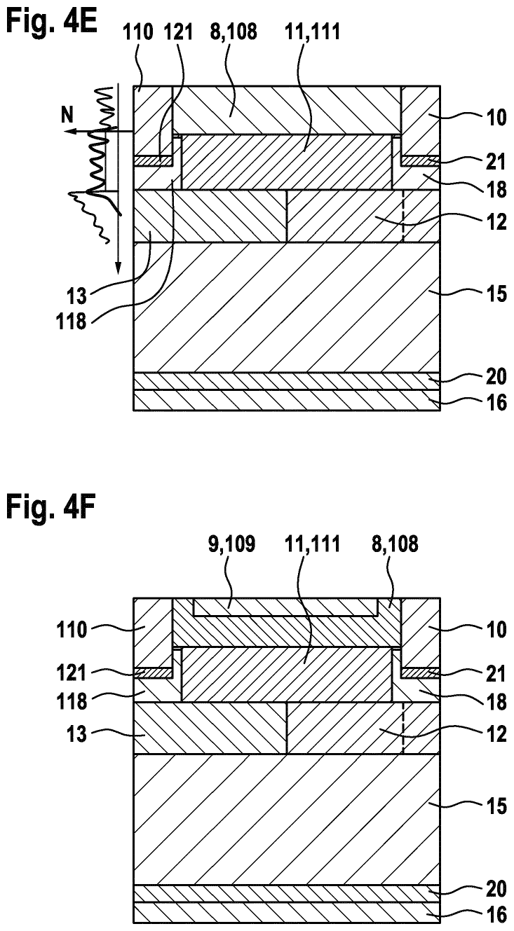

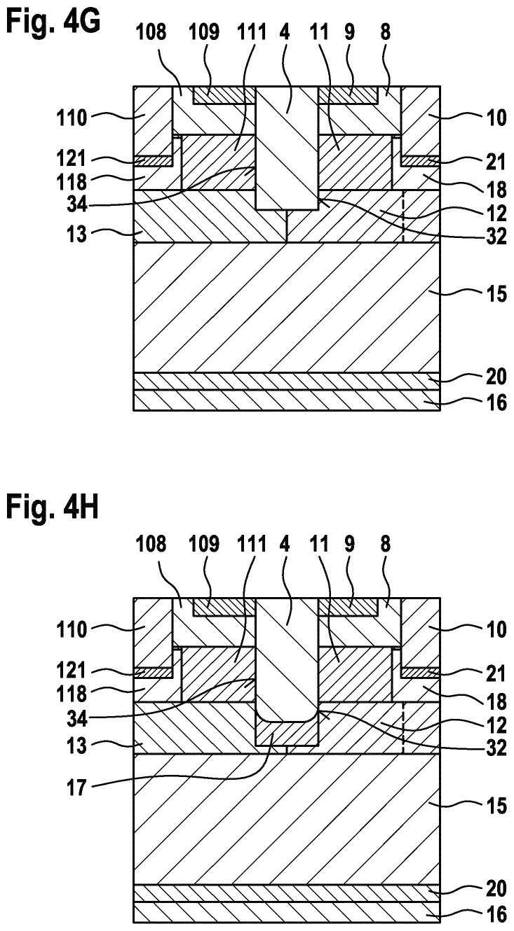

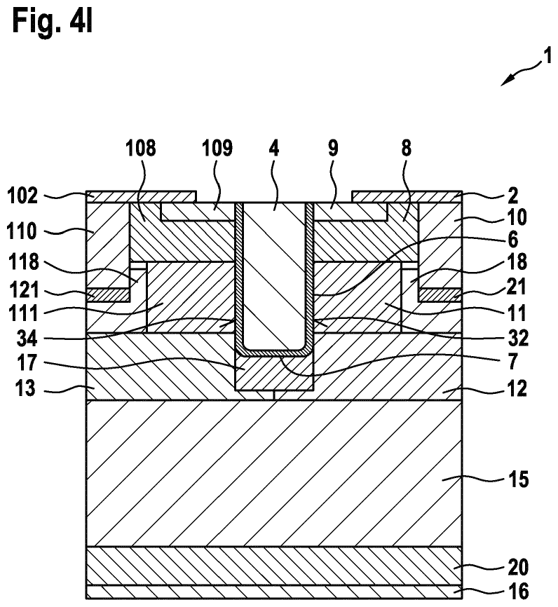

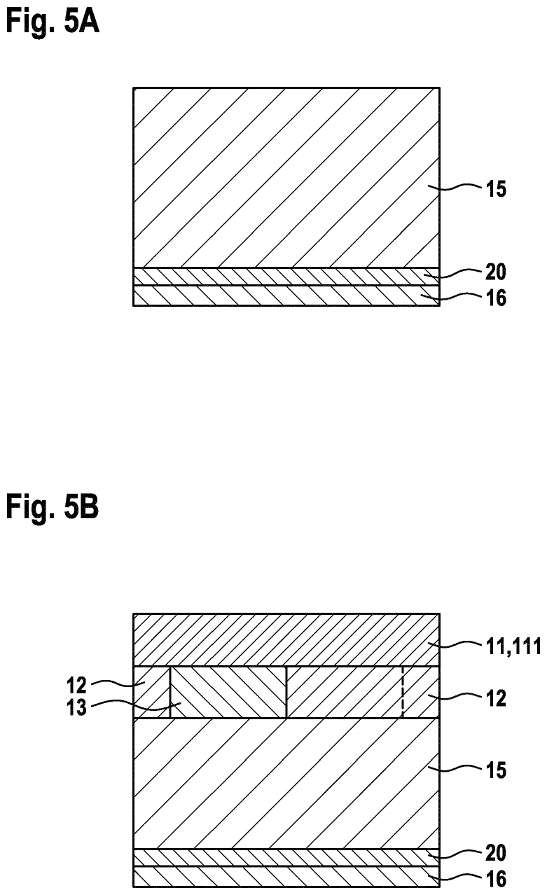

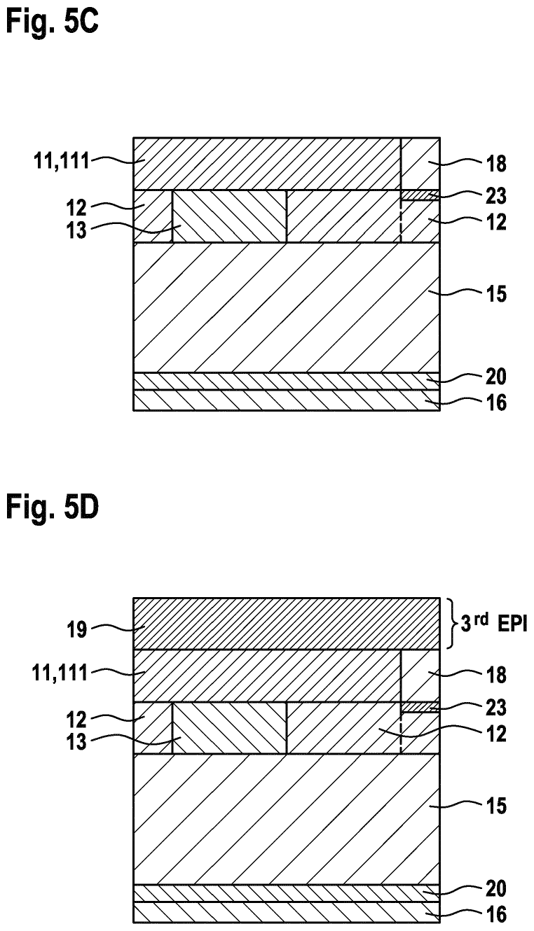

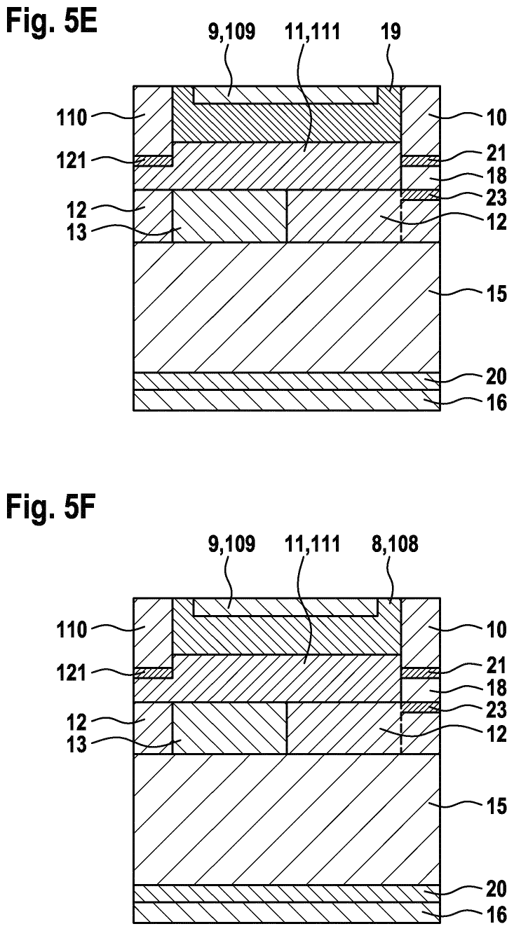

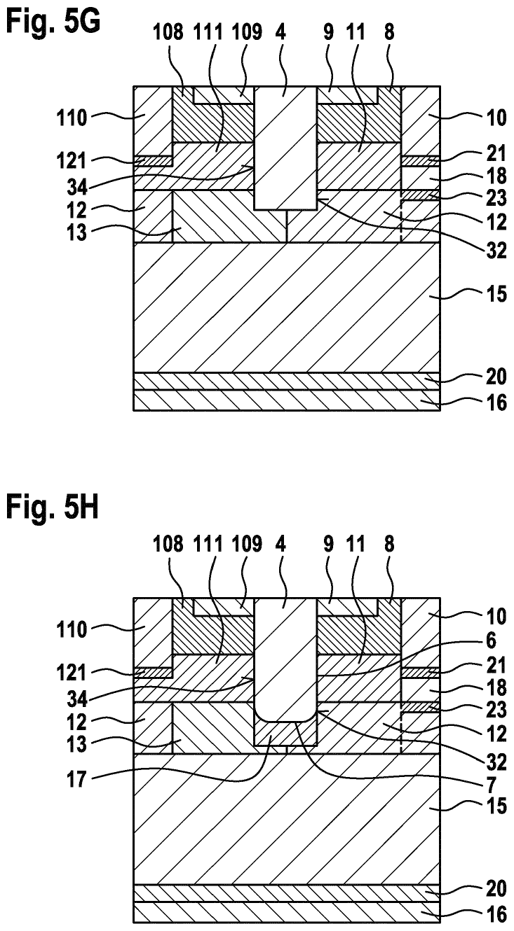

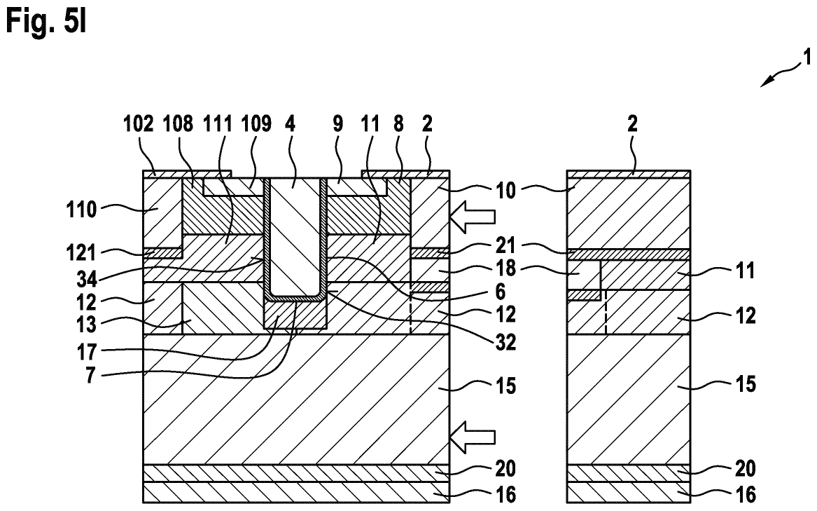

In the specific embodiment from FIG. 2, p⁺-doped regions 10, 110 may be configured in such a way that they do not extend into buried region 12, but only into nSpreading region 11, 111. An electrically conducting connection between buried region 12 and p⁺-doped regions 10, 110 may, for example, be provided with the aid of a p-doped connecting region 18, 118 (p-doped connecting region 118 is not visible in FIG. 2 since it is situated outside the paper plane; however, it is shown in FIG. 4B through FIG. 4I). This is shown by way of example in FIG. 2, FIG. 4I and FIG. 5I. It may be advantageous in the process that a depth of trench 5 extending deeper than p⁺-doped regions 10, 110 is no longer determined by a depth of p⁺-doped regions 10, 110 or their tails 21, 121.

Similarly to p⁺-doped region 10, 110, p-doped connecting region 18, 118 may extend in parallel to trench 5 across its entire length (this is shown by way of example in FIG. 4I), or may only be formed in one or multiple section(s) of the entire length in parallel to trench 5, for example only across buried regions 12. Connecting region 18, 118 may be configured in a pillar-like manner. In FIG. 5I, the right portion of the illustration shows a side view (in the direction of the arrows) of semiconductor device 1 shown on the left side, which makes the pillar-like configuration of connecting region 18 apparent.

Due to the pillar-like design of connecting region 18 (of the pJFET contact region), transverse connections arise in nSpreading region 11, 111 between adjoining semiconductor devices 1 (cells), see also the side view in FIG. 5I in this regard, which additionally cause a forward resistance Rₒₙ of the semiconductor device to become less sensitive to adjustment tolerances of p⁺-doped regions 10, 110 and of connecting region 18, 118 compared to trench 5 since a lateral equalizing current between adjoining cells is made possible or facilitated.

The portion of the electrically conducting connection between the at least one buried region 12 and source region 9, 109 which runs through the semiconductor may be referred to as a connecting zone. In the exemplary embodiment from FIG. 1, the connecting zone includes p⁺-doped regions 10, 110 (and, if necessary, also tails 21, 121), and in the exemplary embodiments from FIG. 2, FIG. 4I and FIG. 5I, it includes p⁺-doped regions 10, 110 (optionally also tails 21, 121) and p-doped connecting regions 18, 118. Shielding region 17 may be electrically connected to the source potential by buried region 12, which, as is explained below in greater detail, may have a “fishbone structure,” and p⁺-doped regions 10, 110 (and optionally connecting regions 18, 118), and thereby represent an additional shielding of gate oxide 6, 7 against high electrical fields which occur at high voltages between drain 3 and source 2, 102.

For the electrically conductive connection between the at least one buried region 12 and source region 9, 109, furthermore at least one metallization 2, 102 may be situated at the upper side of the semiconductor device, e.g., on source region 9, 109 and p⁺-doped regions 10, 110, which may extend across channel region 8, 108. Metallization 2, 102 is at the source potential. The contact between metallization 2, 102 and the semiconductor therebeneath forms an ohmic contact. In the specific embodiment including shielding region 17, it may be connected to the source potential via buried region 12 and p⁺-doped regions 10, 110.

The semiconductor device may furthermore include a rear-side contact 3 at drain potential, which contacts substrate 16.

In various exemplary embodiments, semiconductor device 1 may furthermore include an edge termination for picking up a blocking voltage in the lateral direction and a gate pad (neither one is shown here).

A multitude of semiconductor devices 1 may, as is indicated in FIG. 3, be formed adjoining one another and form a shared active area (a semiconductor unit).

Buried regions 12 are highly schematically illustrated in FIGS. 1 through 5. FIG. 3 indicates the position of trench 5 (or of optional shielding region 17 situated directly therebeneath and of p⁺-doped regions 10, 110 indicated in dotted form). It is apparent that the active area is made up of preferably identical, strip-shaped MOSFETs situated in parallel to one another.

In various specific embodiments, the at least one buried trench 12 may be formed as a multitude of buried regions 12, e.g., strips. The strips may be embedded into n-doped nJFET regions 13. This means that first subarea 32 includes a multitude of first subarea sections, second subarea 34 in each case being situated between two of the first subarea sections.

In various specific embodiments, buried regions 12 may be situated in such a way that they only extend on one side of trench 5 from the edge region to trench 5. In various specific embodiments, buried regions 12 may extend on both sides of trench 5 from the edge region to trench 5, as is shown, for example, in FIG. 3. Each of buried regions 12 may be formed in such a way that it encloses an angle ϕ with the longitudinal direction of trench 5, 0°<ϕ≤90° being possible. Preferred values may be ϕ=45°±5°, or, for example, around 30° or around 60°. All buried regions 12 which are present on the same side of trench 5 may be situated at the same angle ϕ, i.e., be parallel to one another. In various exemplary embodiments, an angle ϕ₁ which buried regions 12 form with the trench 5 on the one side thereof (in FIG. 3, to the left of right trench 5) may be different from an angle ϕ₂ which buried regions 12 form with trench 5 on the other side thereof (in FIG. 3, to the right of right trench 5). For example, ϕ₁=60°, and ϕ₂=30° may apply, as is shown in FIG. 3. In various exemplary embodiments, ϕ₁=ϕ₂ may apply (not shown). In various exemplary embodiments, ϕ₁ and ϕ₂ may be adjoining angles, as is shown in FIG. 3. In this case, buried regions 12 may form a “fishbone structure.” The arrangement of buried regions 12, e.g., the fishbone structure, may continue (preferably) periodically in the lateral directions in parallel and perpendicular to trench 5 and may be formed in the entire active area. In the exemplary embodiment shown in FIG. 3, buried regions 12 extend in two directions which are not in parallel to, and also not perpendicular to, trench 5, and if additional shielding structure 17 is present, even in three directions.

In various exemplary embodiments, it is furthermore possible that buried regions 12 include additional strips which are situated beneath p⁺-doped regions 10, 110 and extend in parallel to trench 5 spaced apart therefrom.

The source potential at metallization 2, 102 may be at the reference potential, for example. In a forward state including a high drain voltage at rear-side contact 3 and a gate voltage below a threshold voltage, a space charge region, proceeding from boundaries between p-doped and n-doped regions, may essentially expand into the n-doped regions due to doping conditions, e.g., into nSpreading region 11, 111, nJFET region 13, nSpreadingFET region 14, and drift region 15. The at least one buried region 12 (and, if necessary, shielding structure 17) may then have the task of protecting gate oxide 6, 7 against excessively high fields. An effective field shielding of a bottom of trench 5 and, in particular, of edges of trench 5 in the area of its roundings may be effectuated by partially enclosing buried (p-doped) regions 12, and possibly shielding structure 17.

In a forward state having a gate voltage above the threshold voltage, an inversion channel on a trench-side surface of channel region 8, 108 (of body region) may be influenced, so that a current flows from drain 3 via substrate 16, drift region (in the narrower sense) 15, nSpreadingFET region 14, nJFET region 13, nSpreading region 11, 111, channel regions 8, 108, and source region 9, 109 to (source) metallization 2, 102. In various exemplary embodiments, resistance R_{Dson} may be reduced, for example, in that nJFET region 13 is configured to be narrower (e.g., narrower) and higher-doped.

FIGS. 4A through 4I show a schematic illustration of a method for manufacturing a semiconductor device according to one specific embodiment, for example one of the above-described semiconductor devices 1.

A so-called double epi concept is employed in the method according to FIGS. 4A through 4I. To simplify matters, nSpreadingFET region 14, which may be manufactured in the course of a first epitaxy or as a deeper implant after the first epitaxy, is not shown here or in FIGS. 5A through 5I.

Based on a (e.g. SiC) wafer substrate 16 including a first epitaxial layer (a drift region in the narrower sense) 15 (FIG. 4A), which is dependent on a desired breakdown voltage of semiconductor device 1 in terms of thickness and the doping concentration, an nJFET region 13 and at least one (e.g. pJFET) buried region 12 may be defined by ion implantation. A second epitaxial layer 118, 18, 19 may then be applied thereto across the entire region of these structures. This layer may be p-doped in a lower portion, which forms connecting regions 18, 118 in the finished semiconductor device, and n-doped in an upper portion (FIG. 4B). Thereafter, p⁺-doped regions 10, 110 may be generated with the aid of ion implantation in such a way that they extend into or up to p-doped buried region 12 of the second epitaxial layer (FIG. 4C). An implant for a channel region (body region) 8, 108 (FIG. 4D) and an implant which redopes the p-doped regions of the second epitaxial layer, away from p⁺-doped regions 10, 100, to n-doped nSpreading regions 1, 111, may be implemented thereupon (FIG. 4E). Connecting regions (pJFET contact regions) 18, 118 may also be created in this way. Thereafter, an implant for source regions 9, 109 (FIG. 4F), a formation of trench 5 (FIG. 4G), and, if necessary, an additional shielding region 17 may be generated beneath the trench by implantation into trench 5 (FIG. 4H). In the process, the trench side wall may be protected during the implantation by a protective layer. Then, after a trench anneal, a filling of trench 5 and an application of metallizations onto the front and rear sides as a drain contact 3, a gate contact (neither one is shown) and a source contact may take place (FIG. 4I). In principle, the order of the implants for channel region 8, 108 and source regions 9, 109 may be interchanged with one another.

FIGS. 5A through 5I show a schematic illustration of a method for manufacturing a semiconductor device according to one specific embodiment, for example one of the above-described semiconductor devices 1.

A so-called triple epi concept may be employed in the method according to FIGS. 5A through 5I. A wafer substrate 16 may essentially correspond (FIG. 5A) to that from FIG. 4A, including the first epitaxial layer. An nJFET region 13 and at least one (e.g., pJFET) buried region 12 may then be defined by ion implantation. An nSpreading region 11, 111 may be applied as a second epitaxial layer above the first epitaxial layer (FIG. 5B). Connecting regions (pJFET contact regions) 18, 118 may be generated with the aid of implantation into the second epitaxial layer (FIG. 5C). Thereupon, a growth of a preferably n-doped third epitaxial layer 19 into a surface of the second epitaxial layer may take place (FIG. 5D). A generation of p⁺-doped regions 10, 100 may take place with the aid of ion implantation. Then, an implant for a source region 9, 109 (FIG. 5E) and a redoping of third epitaxial layer 19, outside p⁺-doped regions 10, 100, to a channel region 8, 108 may take place (FIG. 5F). A trench 5 (FIG. 5G) may be formed, and, if necessary, an additional shielding region 17 may be formed beneath trench 5, by implantation into trench 5 (FIG. 5H). In the process, the trench side wall may be protected during the implantation by a protective layer. Then, after a trench anneal, a filling of trench 5 and an application of metallizations onto the front and rear sides as a drain contact 3, a gate contact (neither one is shown) and a source contact may take place (FIG. 5I). In principle, the order of the implants for channel region 8, 108 and source regions 9, 109 may be interchanged with one another.

A contacting may be implemented with the aid of contact establishment and metallization methods customary in SiC technology, for example in that an Ni contact is alloyed onto the front and rear sides of semiconductor device 1 with a sufficient thermal budget, and thereafter metallizations 2, 3 are applied, e.g., the front-side Al-based or Cu-based metallization 2, and the rear-side Pd/Au-based (drain) metallization 3.

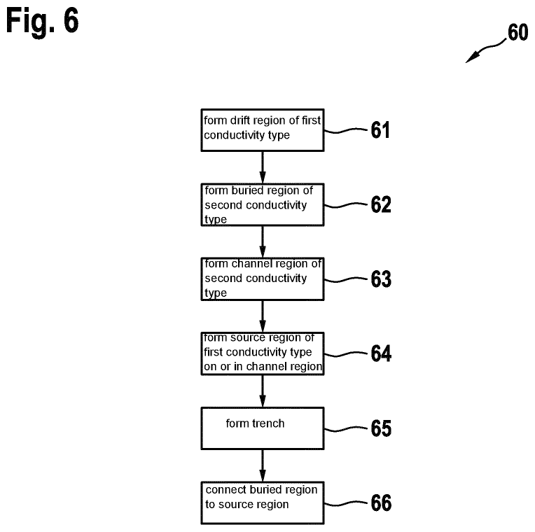

FIG. 6 shows a flowchart 60 of a method for manufacturing a semiconductor device according to one exemplary embodiment.

The method may include forming a drift region of a first conductivity type (at 61), forming at least one buried region of the second conductivity type (at 62), forming a channel region of a second conductivity type on the drift region (at 63), forming a source region of the first conductivity type on the or in the channel region (at 64), forming a trench, which forms an insulated gate and extends through the source region and the channel region so that its bottom is situated in the drift region (at 65), and connecting the buried region to the source region in an electrically conducting manner, it being possible for the at least one buried region to extend within the drift region from an edge region of the drift region to the trench and to be in direct contact with a first subarea of a surface of the trench, it being possible for a second subarea of a surface of the trench to be in direct contact with the drift region, and it being possible for the second conductivity type to be the opposite of the first conductivity type (at 66).

Further advantageous embodiments of the method are derived from the description of the device, and vice versa.

Moreover, method steps according to the present invention may be carried out repeatedly and in a different order than the one described.

If one specific embodiment includes an “and/or” linkage between a first feature and a second feature, this should be read in such a way that the specific embodiment according to one specific embodiment includes both the first feature and the second feature, and according to an additional specific embodiment includes either only the first feature or only the second feature.

1-10. (canceled)

11. A semiconductor device, comprising:
a drift region of a first conductivity type;
a channel region of a second conductivity type on the drift region, the second conductivity type being opposite of the first conductivity type;
a source region of the first conductivity type on or in channel region;
a trench which forms an insulated gate and extends through the source region and the channel region so that a bottom of the trench is situated in the drift region; and
at least one buried region of the second conductivity type, which extends within the drift region from an edge region of the drift region to the trench and is in direct contact with a first subarea of a surface of the trench, a second subarea of a surface of the trench being in direct contact with the drift region, and the buried region being connected to the source region in an electrically conducting manner.

12. The semiconductor device as recited in claim 11, wherein the at least one buried region extends beneath the trench.

13. The semiconductor device as recited in claim 11, wherein the at least one buried region includes a multitude of buried regions, the first subarea of the surface of the trench including a multitude of first subarea sections, and the second subarea being situated between the first subarea sections.

14. The semiconductor device as recited in claim 13, wherein the trench extends laterally in a longitudinal direction and a transverse direction perpendicular to the longitudinal direct, the extension of the trench being longer in the longitudinal direction than in the transverse direction, and the first subarea sections being situated along the longitudinal direction on a first lateral surface of the trench and on a second lateral surface of the trench situated opposite the first lateral surface.

15. The semiconductor device as recited in claim 14, wherein the first subarea sections along the longitudinal direction are alternately situated on the first lateral surface and on the second lateral surface of the trench.

16. The semiconductor device as recited in claim 14, wherein each of the buried regions is formed in such a way that it encloses an angle with the longitudinal direction of the trench.

17. The semiconductor device as recited in claim 16, wherein the buried regions which are in contact with the first subarea sections on the first lateral surface enclose a first angle ϕ₁ with the longitudinal direction of the trench, and the buried regions which are in contact with the first subarea sections on the second lateral surface enclose a second angle ϕ₂ with the longitudinal direction of the trench.

18. The semiconductor device as recited in claim 17, wherein ϕ₁=45°+α and ϕ₂=45°−α for 0°<α<45°.

19. The semiconductor device as recited in claim 18, wherein α=5°.

20. The semiconductor device as recited claim 14, wherein an electrically conducting connection between the buried region and the source region includes a connecting region of the second conductivity type, which extends between an upper surface of the channel region and the buried region.

21. A method for manufacturing a semiconductor device, comprising the following steps:
forming a drift region of a first conductivity type;
forming at least one buried region of a second conductivity type;
forming a channel region of the second conductivity type on the drift region, the second conductivity type being the opposite of the first conductivity type;
forming a source region of the first conductivity type on or in the channel region;
forming a trench which forms an insulated gate and extends through the source region and the channel region, so that a bottom of the trench is situated in the drift region, the at least one buried region extending within the drift region from an edge region of the drift region to the trench and being in direct contact with a first subarea of a surface of the trench, a second subarea of a surface of the trench being in direct contact with a drift region; and
connecting the buried region to the source region in an electrically conducting manner.
